(19) United States
(12) Patent Application Publication
(10) Pub. No.: US 2026/0134917 A1
(43) Pub. Date: May 14, 2026

(54) CROSSBAR CIRCUITS FOR ANALOG COMPUTING

(71) Applicants: TetraMem Inc., San Jose, CA (US); University of Southern California, Los Angeles, CA (US); Government of the United States as Represented by the Secretary of the Air Force, Wright-Patterson AFB, OH (US)

(72) Inventors: Wenhao Song, Los Angeles, CA (US); Jianhua Yang, Los Angeles, CA (US); Mark Barnell, Syracuse, NY (US); Qing Wu, Rome, NY (US); Mingyi Rao, San Jose, CA (US); Miao Hu, San Jose, CA (US)

(73) Assignees: TetraMem Inc., San Jose, CA (US); University of Southern California, Los Angeles, CA (US); Government of the United States as Represented by the Secretary of the Air Force, Wright-Patterson AFB, OH (US)

(21) Appl. No.: 19/428,033

(22) Filed: Dec. 19, 2025

Related U.S. Application Data
(63) Continuation of application No. PCT/US2024/034858, filed on Jun. 20, 2024.
(60) Provisional application No. 63/509,204, filed on Jun. 20, 2023.

(51) Int. Cl. G11C 13/00; G06G 7/06

(52) U.S. Cl. CPC G11C 13/0069; G11C 13/003; G06G 7/06; G11C 13/0004; G11C 2213/79

(57) ABSTRACT

The present disclosure provides a crossbar circuit for performing in-memory computing and methods for performing vector-matrix multiplication (VMM) using the crossbar circuit. The crossbar circuit may include crossbar subarrays, trans-impedance amplifiers (TIAs), and analog-to-digital converter (ADCs). The crossbar subarrays may be programmed sequentially to compensate for residual errors associated with the previously programmed crossbar subarrays. For example, a first crossbar subarray may be programmed based on target conductance values. A second crossbar subarray may then be programmed based on the programming error associated with the first crossbar subarray. After the programming of the crossbar subarrays, input signals representative of an input matrix may be applied to the programmed crossbar subarrays. The TIAs may generate output voltages representative of accumulated current on the bit lines of the programmed crossbar subarrays. The DACs may convert the output voltage of the TIAs into digital outputs representing an output of a VMM operation.

### CROSS-REFERENCE TO RELATED APPLICATIONS

The present application is a continuation of PCT/US2024/034858, filed Jun. 20, 2024, entitled “Crossbar Circuits for Analog Computing,” which claims the benefits of U.S. Patent Application No. 63/509,204, entitled “Memristor Array for Analog Computing,” filed Jun. 20, 2023, each of which is incorporated by reference in its entirety.

### GOVERNMENT INTEREST

This invention was made with government support under FA9550-19-1-0213 awarded by the Air Force Office of Scientific Research (AFOSR) and FA9550-19-1-0213 awarded by the Air Force Research Laboratory (AFRL). The government has certain rights in the invention.

### TECHNICAL FIELD

This disclosure relates generally to the field of analog computer processing and, more particularly, to crossbar circuits for analog computing and methods for performing in-memory computing using crossbar circuits.

### BACKGROUND

A crossbar circuit may refer to a circuit structure with interconnecting electrically conductive lines sandwiching a memory element, such as a resistive switching material, at their intersections. The resistive switching material may include, for example, a memristor (also referred to as resistive random-access memory (RRAM or ReRAM)). Crossbar circuits may be used to implement in-memory computing applications, non-volatile solid-state memory, image processing applications, neural networks, etc.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, methods for programming a crossbar circuit are provided. The methods include: programming a first plurality of memory elements of a first crossbar subarray based on first target conductance values; determining first programmed conductance values of the first plurality of memory elements by performing a read operation; determining a first residual error representing a difference between the first target conductance values and the first programmed conductance values; and programming a second plurality of memory elements of a second crossbar subarray based on the first residual error.

In some embodiments, programming the first plurality of memory elements of the first crossbar subarray includes applying a first plurality of programming signals to the first plurality of memory elements.

In some embodiments, the first target conductance values are determined by mapping an initial residual matrix to a first target conductance matrix within a programmable conductance range of the first plurality of memory elements.

In some embodiments, programming the second plurality of memory elements of the second crossbar subarray based on the first residual error includes determining second target conductance values based on the first residual error and programming the second plurality of memory elements of the second crossbar subarray based on the second target conductance values.

In some embodiments, the methods further include determining a second residual error representing a difference between the second target conductance values and second programmed conductance values of the second plurality of memory elements and programming a third plurality of memory elements of a third crossbar subarray based on the second residual error.

In some embodiments, programming the second plurality of memory elements of the second crossbar subarray based on the first residual error includes mapping the first residual error to a second target conductance matrix.

In some embodiments, programming the second plurality of memory elements of the second crossbar subarray based on the second target conductance values includes applying a second plurality of programming signals to the second plurality of memory elements.

In some embodiments, the first plurality of memory elements is connected to a first plurality of bit lines and a first plurality of word lines, and the second plurality of memory elements is connected to a second plurality of bit lines and a second plurality of word lines.

In some embodiments, the methods further include: generating, using an analog-to-digital converter, a digital output based at least in part on a first output voltage and a second output voltage, wherein the first output voltage represents first accumulated current on a first bit line of the first plurality of bit lines, and wherein the second output voltage represents second accumulated current on a second bit line of the second plurality of bit lines.

In some embodiments, the methods further include: generating, using a first trans-impedance amplifier connected to the first bit line of the first plurality of bit lines, the first output voltage; and generating, using a second trans-impedance amplifier connected to the second bit line of the second plurality of bit lines, the second output voltage.

In some embodiments, the first plurality of memory elements includes at least one of a memristor, a phase-change memory (PCM) device, a floating gate device, a spintronic device, or a ferroelectric device.

According to one or more aspects of the present disclosure, a crossbar circuit is provided. The crossbar circuit includes: a first crossbar subarray including a first plurality of word lines, a first plurality of bit lines, and a first plurality of memory elements connected to the first plurality of word lines and the first plurality of bit lines; a second crossbar subarray including a second plurality of word lines, a second plurality of bit lines, and a second plurality of memory elements connected to the second plurality of word lines and the second plurality of bit lines; a first trans-impedance amplifier (TIA) connected to a first bit line of the first plurality of bit lines; a second TIA connected to a second bit line of the second plurality of bit lines; and a first analog-to-digital converter (ADC) configured to generate a first digital output based at least in part on a first output voltage of the first TIA and a second output voltage of the second TIA.

In some embodiments, the first TIA is configured to generate the first output voltage based on accumulated current on the first bit line, and wherein the second TIA is configured to generate the second output voltage based on accumulated current on the second bit line.

In some embodiments, the crossbar circuit further includes a third crossbar subarray including a third plurality of word lines, a third plurality of bit lines, and a third plurality of memory elements connected to the third plurality of word lines and the third plurality of bit lines; and a third TIA connecting to a third bit line of the third plurality of bit lines, wherein the first ADC is further configured to generate the first digital output based at least in part on a third output voltage of the third TIA.

In some embodiments, the crossbar circuit further includes a fourth TIA connected to a fourth bit line of the first plurality of bit lines; a fifth TIA connected to a fifth bit line of the second plurality of bit lines; and a second ADC configured to generate a second digital output based at least in part on a fourth output voltage of the fourth TIA and a fifth output voltage of the fifth TIA.

In some embodiments, the crossbar circuit further includes a sixth TIA connected to a sixth bit line of the third plurality of bit lines, wherein the second ADC is further configured to generate the second digital output based at least in part on a sixth output voltage of the sixth TIA.

In some embodiments, the crossbar circuit further includes a programming circuit configured to: program the first plurality of memory elements based on first target conductance values; perform a first read operation to determine programmed conductance values of the first plurality of memory elements; determine a first residual error representing a difference between the first target conductance values and the first programmed conductance values; and program the second plurality of memory elements based on the first residual error.

In some embodiments, the programming circuit is further configured to: determine second programmed conductance values of the second plurality of memory elements; determine a second residual error representing a difference between the second target conductance values and the second programmed conductance values; and program a third plurality of memory elements of a third crossbar subarray based on the second residual error.

In some embodiments, the first plurality of memory elements includes at least one of a memristor, a phase-change memory (PCM) device, a floating gate device, a spintronic device, or a ferroelectric device.

In some embodiments, the first plurality of memory elements includes a one-transistor-one-resistor (1T1R) configuration.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a schematic diagram illustrating a conventional crossbar architecture utilizing a bit-slicing approach.

FIG. 2A is a diagram illustrating an example of a crossbar circuit architecture in accordance with some embodiments of the present disclosure.

FIG. 2B is a schematic diagram illustrating an example memory element in accordance with some embodiments of the present disclosure.

FIG. 3 is a flowchart illustrating an example process for programming a crossbar circuit in accordance with some embodiments of the present disclosure.

FIG. 4 is a flowchart illustrating an example process for performing a VMM operation using a crossbar circuit in accordance with some embodiments of the present disclosure.

FIG. 5 is a diagram illustrating residual errors involved in programming a numerical value using three crossbar subarrays in accordance with some embodiments of the present disclosure.

FIG. 6A illustrates a final conductance map of a 64×64 region after 30 programming cycles performed on a crossbar circuit in accordance with some embodiments of the present disclosure.

FIG. 6B illustrates an absolute error map after 30 programming cycles performed on the crossbar circuit described in connection with FIG. 6A.

FIGS. 7A-7H show experimental results from a Poisson solver utilizing arbitrary precision programming across three crossbar subarrays.

FIGS. 8A-8F illustrate experimental results relating to a hardware implementation of a recursive least-squares filter with arbitrary precision programming.

FIG. 9A is a graph illustrating the number of iterations needed for convergence across various mesh sizes.

FIG. 9B is a graph illustrating the energy consumption of a crossbar circuit in accordance with the present disclosure compared with an ASIC design running at approximately the same speed.

FIG. 9C illustrates the real part of a Discrete Fourier Transform (DFT) matrix used in a Navier-Stokes (N-S) equation solver.

FIG. 9D is a quiver plot illustrating the solved velocity field of an N-S equation at t=4.8 s solved by MATLAB.

FIGS. 9E-9I are quiver plots illustrating the solved velocity field of an N-S equation at t=4.8 s solved by memristor simulation using one to five subarrays.

FIG. 9J is a quiver plot illustrating the solved velocity and magnetic flux density field of an MHD problem at t=2 by MATLAB.

FIG. 9K is a quiver plot illustrating the solved velocity and magnetic flux density field of an MHD problem at t=2 by memristor simulation using five subarrays.

### DETAILED DESCRIPTION

Aspects of the disclosure provide crossbar circuits and mechanisms for programming crossbar circuits for analog computing.

Complex systems, including complex physical systems, may be described by coupled nonlinear equations that may be analyzed simultaneously at multiple spatiotemporal scales, such as to predict the behavior of such systems, elements in such systems, etc. However, complex systems may be too complex for analytical techniques (e.g., for determining analytical solutions), and direct numerical computation may be hindered by the “curse of dimensionality,” which may require exponentially increasing resources as the size of the problem increases. These complex systems can range from nanoscale problems in material modeling to large-scale problems in climate science. While the need for accurate and high-performance computing solutions is growing, traditional von Neumann computing architectures may reach their limits in terms of speed, power consumption, and infrastructure.

In-memory computing may circumvent the memory-processor bottleneck inherent to von Neumann architectures. In-memory computing in crossbars can execute a large vector-matrix multiplication (VMM) in the analog domain within one computing cycle [O(1) time complexity] by exploiting Ohm's law and Kirchhoff's current law Iₒ=G^{T}Vᵢ, where Vᵢ is the input voltage vector, G^{T} is the transposed conductance matrix, and Iₒ is the output current vector from the crossbar. In the digital domain, such computation requires N² multiplication and additions, where Nis the vector size. To achieve efficient in-memory computing, various emerging devices, such as floating gate transistors, phase-change, ferroelectric, magnetic, organic, and metal oxide switching materials, have been studied intensively to enable the parallel computation of matrix operations in nonvolatile memory crossbars. However, technical challenges, such as reading noises and writing variabilities (caused by device-to-device inhomogeneities), have limited the scalability and precision required by many applications, such as high-performance scientific computing and in situ training for neural networks.

The present disclosure provides a crossbar circuit architecture and mechanisms for performing in-memory computing using the crossbar circuit architecture. The crossbar circuit architecture may include multiple crossbar subarrays of memory elements, trans-impedance amplifiers (TIAs), analog-to-digital converters (ADCs), and other suitable components for performing VMM. In some embodiments, each of the crossbar subarrays may include a memristor array. To perform a VMM represented as Y=XA, where Y represents an output matrix, X represents an input matrix, and A represents a matrix of coefficients, one or more of the crossbar subarrays may be programmed to conductance representative of matrix A. For example, the crossbar subarrays may be sequentially programmed to dynamically compensate for residual errors of the previously programmed subarray(s). In some embodiments, a weighted sum of multiple memory elements of multiple crossbar subarrays may be programmed to represent one number, in which subsequently programmed devices are used to compensate for preceding programming errors.

After the programming of the crossbar subarrays, input signals representative of matrix X may be applied to the programmed crossbar subarrays. The TIAs may generate output voltages representative of accumulated current on the respective bit lines of the programmed crossbar subarrays. The DACs may generate digital output based on the output voltage of the TIAs. As such, most of the VMM can be performed at arbitrarily high precision before being output as a digital result. The entire VMM process is analog, with digitization occurring only at the final step. Multiple subarrays can share one ADC, saving significant area and power consumed by this component, as well as reducing the need for post-processing digital circuits such as bit shifters and adders for partial products used in the traditional approach.

The circuit architecture and programming methods disclosed herein efficiently represent high-precision numbers using multiple relatively low-precision analog devices, such as memristors. This approach significantly reduces overhead in circuitry, energy, and latency compared to existing quantization methods. The circuit architecture and the programming methods may be used for high-precision solutions for multiple scientific computing tasks, such as static and time-evolving partial differential equations (PDEs), maintaining a substantial power efficiency advantage over conventional digital approaches. Examples of the PDEs include Laplace and Poisson equations, Navier-Stokes (N-S) equations, magnetohydrodynamics (MHD) problems, adaptive filters like recursive least square (RLS) filters, etc.

While the present techniques are susceptible to various modifications and alternative forms, specific embodiments thereof are shown by way of example in the drawings included or described herein. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims. Further, the description of problems (to be solved, with other techniques, technical problems, etc.) should not be read to imply that all embodiments must fully eliminate those problems, or that any techniques suffering to some degree from such problems are disclaimed, as various inventive techniques are described and various engineering and cost trade-offs may result in only subsets of such problems being mitigated only partially by some embodiments consistent with the present techniques.

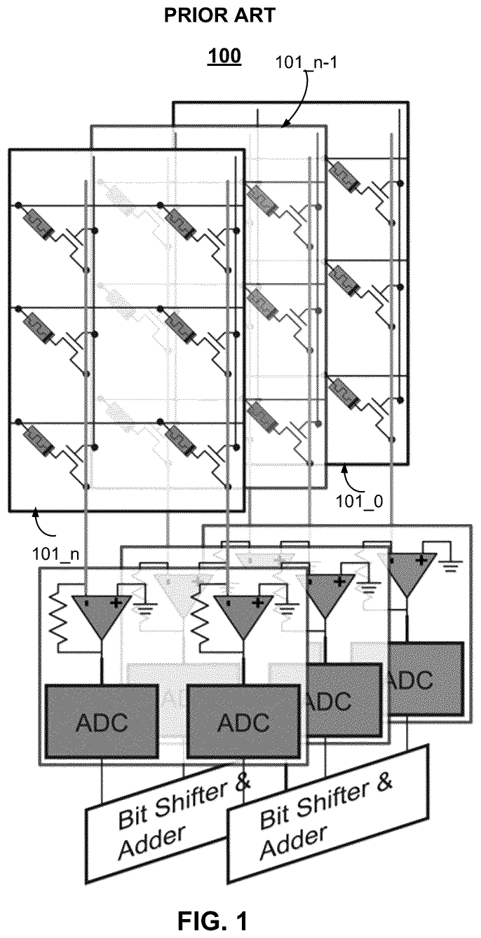

FIG. 1 is a schematic diagram illustrating a conventional crossbar architecture 100 with a bit-slicing approach.

The conventional crossbar architecture 100 adopts a bit-slicing approach to perform a VMM operation that may be represented as Y=XA, where Y denotes the VMM product, X denotes the input, and A denotes a predetermined weight matrix. In particular, the weight matrix A is mapped to the conductance of crossbar circuits 101_n, 101_n−1, . . . , 101_0 as follows:

$$A = {2}^{n} {G}_{n} + {2}^{n - 1} {G}_{n - 1} + … + {2}^{0} {G}_{0} , \qquad ( 1 )$$

wherein Gₙ, Gₙ₋₁, and G₀ represent the conductance of the crossbar circuits 101_n, 101_n−1, . . . , 101_0, respectively.

Crossbar architecture 100 follows the same paradigm as digital circuits, which is not error tolerant. In digital circuit design, each number is represented by multiple bits. During multiplication, each bit in the multiplier is multiplied with each bit in the multiplicand to get many partial products. As a result, a multiplier circuit has a group of bit shifters and adders that add the partial products. Such an approach is inherited and expanded to arrays in traditional in-memory computing architecture, forming the so-called bit-slicing approach. In that approach, the memory elements are bound into very limited (usually binary) predetermined states, with the weight matrix and input matrices sliced into multiple bit planes (only weight planes are shown in FIG. 1, and the input planes are omitted for simplicity), and partial VMMs are performed in those bit planes to obtain many partial products. Those partial products are then quantized and combined using additional digital circuitry such as ADCs, shifters, and adders to get the full VMM product. That is as complex as the digital multiplier, if not more. On the algorithm side, the same computing algorithm optimized for digital computing is typically used. Therefore, the accuracy of the VMM result relies heavily on the programming accuracy of each cell in the array. This approach forces analog devices to behave like digital devices, negating the advantages of analog devices and analog computing.

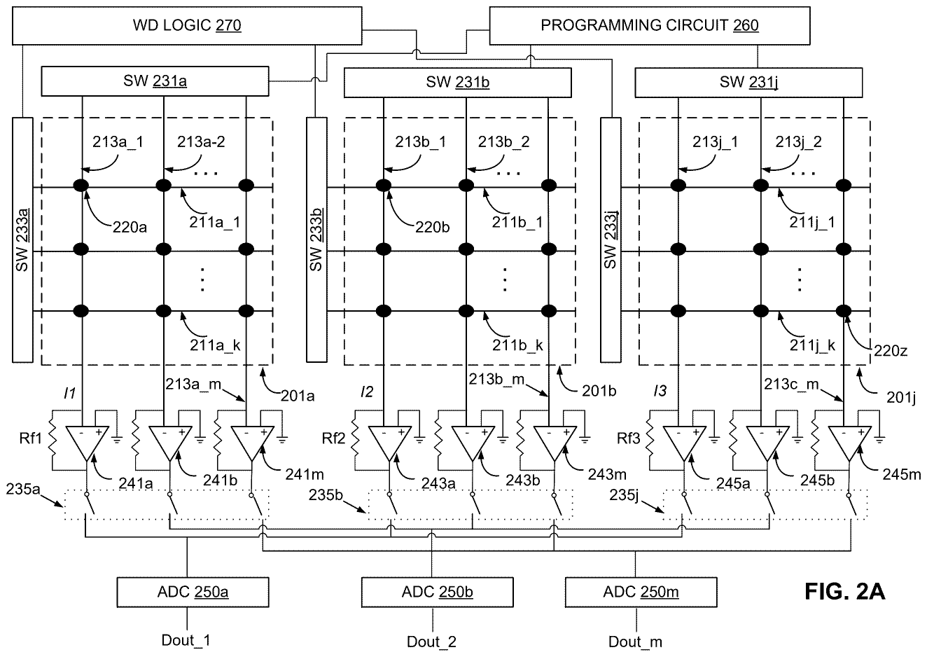

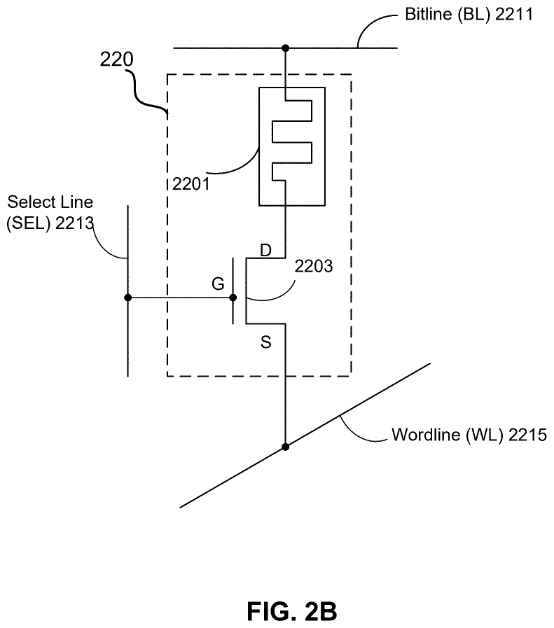

FIG. 2A is a schematic diagram illustrating an example 200 of a crossbar circuit architecture in accordance with some embodiments of the present disclosure. As shown, crossbar circuit 200 may include a plurality of crossbar subarrays 201a, 201b, . . . , 201j. Crossbar subarrays 201a, 201b, and 201j may be connected to a programming circuit 260 via switches (SW) 231a, 231b, . . . , 231j, respectively. Crossbar subarrays 201a, 201b, . . . , 201j May be connected to a word line (WD) logic 270 via switches 233a, 233b, . . . , 233j, respectively. WD logic 270 may include any suitable component for applying input signals to selected memory elements of crossbar subarrays 201a, 201b, . . . , 201j, such as one or more digital-to-analog converters (DACs), amplifiers, etc. Each of the input signals may be a voltage signal, a current signal, etc.

Each of the crossbar subarrays may include a plurality of interconnecting electrically conductive wires and memory elements (e.g., memory elements 220a, . . . , 220b, . . . , 220z) connected to the intersection of the conductive wires. For example, crossbar subarray 201a (also referred to as the “first crossbar subarray”) may include a first plurality of word lines 211a_1, 211a_2, . . . , 211a_k, a first plurality of bit lines 213a_1, . . . , 213a_m, and a first plurality of memory elements. Each of the first plurality of memory elements may be connected to one of the first plurality of word lines and one of the first plurality of bit lines. The number of the first plurality of bit lines and the number of the first plurality of word lines may or may not be the same. Similarly, crossbar subarray 201b (also referred to as the “second crossbar subarray”) may include a second plurality of word lines 211b_1, 211b_2, . . . , 211b_k, a second plurality of bit lines 213b_1, . . . , 213b_m, and a second plurality of word lines and the second plurality of bit lines. Crossbar subarray 201j (also referred to as the “third crossbar subarray”) may include a third plurality of word lines 211j_1, 211j_2, . . . , 211j_k, a third plurality of bit lines 213j_1, . . . , 213j_m, and a third plurality of memory elements connected to the third plurality of word lines and the third plurality of bit lines.

Crossbar subarrays 201a, 201b, . . . , 201j may be physically arranged in any suitable manner. In some embodiments, crossbar subarrays 201a, 201b, . . . , 201j may be physically placed horizontally, vertically, or three-dimensionally (3D) stacked at different planes to form a 3-D crossbar circuit arrangement. The crossbar subarrays may be collectively regarded as a crossbar array of memory elements. While a certain number of crossbar subarrays are shown in FIG. 2A, this is merely illustrative. Crossbar circuit 200 may include any suitable number of crossbar subarrays to implement various applications.

Each memory element 220a, . . . , 220z may be and/or include any suitable device with programmable resistance, such as memristors, phase-change memory (PCM) devices, floating gates, spintronic devices, ferroelectric devices, etc. In some embodiments, one or more memory elements 220a-220z may include a memory element as described in connection with FIG. 2B.

Crossbar circuit 200 may further include a summation circuit that may convert summed current on one or more bit lines of crossbar circuit 200 into one or more digital outputs. The summation circuit may include trans-impedance amplifiers (TIAs) 241a, 241b, . . . , 241m, 243a, 243b, . . . , 243m, 245a, 245b, 245m and one or more analog-to-digital converters (ADCs) 250a, . . . , 250m.

Each TIA 241a, . . . , 241m, 243a, . . . , 243m, 245a, . . . , 245m may convert the accumulated current on a respective bit line into a voltage signal. For example, TIA 241a (also referred to as the “first TIA”) may convert the accumulated current on bit line 213a_1 (I1) into a voltage. TIA 243a (also referred to as the “second TIA”) may convert the accumulated current on bit line 213b_1 (I2) into a second voltage. TIA 245a (also referred to as the “third TIA”) may convert the accumulated current on bit line 213j-1 (I3) into a third voltage. In some embodiments, each TIA 241a, . . . , 245m may be connected to a feedback resistor. For example, TIAs 241a, 243a, and 245a may be connected to feedback resistors R_{f1}, R_{f2}, and R_{f3}, respectively. TIAs 241a, . . . , 241m, 243a, . . . , 243m, 245a, . . . , 245m may be selectively connected to an ADC 250a, 250b, . . . , 250m via switches 235a, 235b, . . . , and 235j, respectively. Each ADC 250a, . . . , 250m may convert the outputs produced by its corresponding TIAs into a digital output. For example, a first ADC 250a may convert the outputs of the TIAs connected to the first bit line of each crossbar array of the crossbar circuit 200 (e.g., the outputs of TIAs 241a, 243a, . . . , 245a) into a first digital output (Dout_1). A second ADC 250b may convert the outputs of the TIAs connected to the second bit line of each crossbar array of the crossbar circuit 200 (e.g., the outputs of TIAs 241b, 243b, . . . , 245b) into a second digital output (Dout_2). ADC 250m may convert the outputs of the TIAs connected to the mth bit line of each crossbar array (e.g., the outputs of TIAs 241m, 243m, . . . , 245m) into the mth digital output (Dout_m).

Programming circuit 260 may program the memory elements selected by switches 231a, . . . , 231n to suitable conductance values. Programming circuit 260 may include any suitable component for applying programming signals to selected memory elements, such as one or more DACs, amplifiers, etc. Programming a memory element may involve applying a suitable voltage signal or current signal across the memory element. The resistance of each memory element may be electrically switched between a high-resistance state and a low-resistance state. Setting a memory element may involve switching the resistance of the cross-point from the high-resistance state to the low-resistance state. Resetting the memory element may involve switching the resistance of the cross-point from the low-resistance state to the high-resistance state. A set/reset operation can be applied multiple times on the same device using a multi-pulse feedback scheme to program memristors to the desired conductance values within the error tolerance.

Crossbar subarrays 201a, 201b, . . . , 201j may be programmed to perform parallel weighted voltage multiplication and current summation. For example, an input voltage signal may be applied to one or more selected word lines. The input signal may flow through the memory elements of the selected word lines. The conductance of the memory element may be tuned to a specific value (also referred to as a “weight”). By Ohm's law, the input voltage multiplies the cross-point conductance and generates a current from the memory element. By Kirchhoff's law, the summation of the current passing the devices on each column generates the current as the output signal, which may be read from the columns (e.g., outputs of the ADCs). According to Ohm's law and Kirchhoff's current law, the input-output relationship of the crossbar array can be represented as I=VG, wherein/represents the output signal matrix as current; V′ represents the input signal matrix as voltage; and G represents the conductance matrix of the memory elements. As such, the input signal is weighted at each of the memory elements by its conductance according to Ohm's law. The weighted current is output via each bit line and may accumulate according to Kirchhoff's current law. This may enable in-memory computing (IMC) via parallel multiplications and summations performed in the crossbar subarrays.

Crossbar subarrays 201a, . . . , 201j may be configured to perform vector-matrix multiplication (VMM). A VMM operation may be represented as Y=XA, wherein each of Y, X, A represents a respective matrix. Matrix A may represent pre-trained neural network weight values, a matrix of predetermined coefficients, etc. As an example, input matrix X may be mapped to the input voltage V of a crossbar subarray 201a, . . . , 201j. Matrix A may be mapped to conductance values G. The output current/may be read and mapped back to output results Y. In some embodiments, crossbar circuit 200 may be configured to implement a portion of a neural network by performing VMMs.

To perform a VMM operation represented as Y=XA, programming circuit 260 may program selected memory elements of one or more crossbar subarrays to conductance values representing matrix A. A particular number of subarrays may be selected for programming to achieve arbitrary programming precision. The selected subarrays may be programmed sequentially. For example, while crossbar subarray 201a is programmed, crossbar subarrays 201b, . . . , 201j may be disconnected from programming circuit 260 (e.g., by opening switches 231b, . . . , 231n).

In some embodiments, a weighted sum of multiple memory elements may be programmed to represent one number, in which subsequently programmed memory elements are used to compensate for preceding programming errors. For example, matrix A may be used as an initial residual matrix (R₀) to program crossbar subarray 201a. In particular, the initial residual matrix (R₀) may be mapped to a first target conductance matrix (G) target) within the programmable conductance range of the memory elements of crossbar subarray 201a (also referred to as the “first target conductance matrix”). The first target conductance matrix (G_{1_target}) contains target conductance values to which the memory elements in crossbar subarray 201a are to be programmed (also referred to as the “first target conductance values”). Given that matrix A can include both positive and negative elements while conductance, as a physical quantity related to the device, must be positive and within a certain dynamic range, a mapping method capable of converting both positive and negative values into a given positive range may be employed. In one implementation, a linear mapping method may be used to map Roto G_{1_target}. The linear mapping method may be expressed as:

$${G}_{1 \_ target}^{T} = {K}_{1} {R}_{0} + {B}_{1} , \qquad ( 2 )$$

where K is a diagonal matrix for scaling, and B is a global offset matrix where the elements within the same row are identical so that the entire column of memory elements is shifted by the same value. In another implementation, differential pairs may be used to map R₀ to G_{1_target}, where two memory elements may be used to represent one number, and the number is proportional to the difference in the conductance values of the two memory elements.

Crossbar subarray 201a may then be programmed based on the first target conductance matrix G_{1_target}. For example, programming circuit 260 may apply one or more first programming signals to one or more selected memory elements of crossbar subarray 201a to program the selected memory elements to the first target conductance values. In some embodiments, the nth row of the memory elements may be programmed to conductance values corresponding to B₁. Because the memory elements are analog devices, there may be a programming error between the first target conductance matrix (G_{1_target}) and a conductance matrix (G₁) containing the realized conductance values of the memory elements of crossbar subarray 201a after programming. G₁ may be inversely mapped to a numerical matrix A₁. A first residual matrix (R₁) representative of a difference between A₁ and the initial residual matrix A may then be determined. The first residual matrix (R₁) may be used to program crossbar subarray 201b. For example, the first residual matrix (R₁) may be mapped to a second target conductance matrix (G_{2_target}) in a similar manner to how R₀ is mapped to G_{1_target}. The second target conductance matrix (G_{2_target}) contains target conductance values to which the memory elements in crossbar subarray 201b are to be programmed (also referred to as the “second target conductance values”). Crossbar subarray 201b may then be programmed based on the second target conductance matrix (G_{2_target}). After the programming of crossbar subarray 201b, the programmed conductance values of the memory elements of crossbar subarray 201b may be measured and may be represented as a conductance matrix G₂. A second residual error related to the programming of crossbar subarray 201b may be determined. For example, G₂ may be inversely mapped to a second numerical matrix (A₂). The second residual error (R₂) may then be determined as follows:

$${R}_{2} = A - ( {A}_{1} + {A}_{2} ) = {R}_{1} - {A}_{2} . \qquad ( 3 )$$

As such, the second residual error (R₂) may correspond to a difference between the first residual error (R₁) and the second numerical matrix (A₂) and/or the accumulated programming errors associated with the previously programmed crossbar subarrays (e.g., a difference between matrix A and the sum of the first numerical matrix (A₁) and the second numerical matrix (A₂)). The second residual error (R₂) may be used to program crossbar subarray 201j. For example, the second residual error (R₂) may be mapped to a third target conductance matrix G_{3_target}. The third crossbar subarray may be programmed based on the third target conductance matrix.

The subsequent crossbar subarrays may be programmed based on programming errors associated with the previously programmed crossbar subarrays based on the following programming algorithm. The target mathematical matrix A is represented by a conductance matrix G, and G=f(A). In some embodiments, f(A)=KA+B, where K is a diagonal matrix and B serves as a global offset matrix where the elements within the same row are identical so that the entire column of memristors are shifted by the same value. For each subarray, programming methods such as a write-verify method with a limited number of iterations or a one-shot method may be used. The write-verify method may involve writing data to each subarray and then verifying the correctness of the data written. This process may be repeated for a predefined number of iterations to ensure reliability. Alternatively, the one-shot method writes data once without subsequent verification. The programming algorithm involves:

```
Initialization: R₀ = A, n is the number of subarrays to use.
For i = 1:n
  Map the numerical residual matrix to conductance by
  G_{i,target} = fᵢ(Rᵢ−1), with K and B chosen such that each column of
  G_{i,target} is mapped to the full conductance range of the memory
  elements.
  Write G_{i,target} to the subarray i and get a different Gᵢ ≈ G_{i,target}
  Inverse map the conductance to the numerical matrix by Aᵢ =
  f⁻¹(Gᵢ)
  Compute the residual matrix Rᵢ = Rᵢ₋₁ − Aᵢ=A−ΣAᵢ
Endfor
```

The conductance of the programmed crossbar subarrays may be represented as

$$\sum {A}_{i} = \sum {K}_{i} {G}_{i} . \qquad ( 4 )$$

After programming the crossbar subarrays, crossbar circuit 200 may perform a VMM operation. The word lines of the programmed crossbar subarrays may be connected to WD logic 270 through switches 233a, 233b, . . . , 233n. WD logic 270 may provide input voltage signals (voltage signals, current signals) representative of an input matrix X to the programmed crossbar subarrays. The accumulated current on the bit lines of the programmed crossbar subarrays may be converted to voltage outputs through the TIAs connected to the programmed crossbar subarrays. The ADCs may then sample and convert the voltage outputs to digital outputs. For example, TIA 241a may convert the accumulated current on bit line 213a-1 into a first voltage output. TIA 243a may convert the accumulated current on bit line 213b-1 into a second voltage output. TIA 245a may convert the accumulated current on bit line 213j-1 into a third voltage output. The first voltage output, the second voltage output, and the third voltage output may be provided to ADC 250a as input. In some embodiments, the voltage outputs may be provided to ADC 250a via an active voltage summation and averaging circuit (not shown in FIG. 2A). In such embodiments, when three crossbar subarrays are used for VMM, the input of ADC 250a may correspond to a voltage V₀ represented as follows:

$$- {V}_{0} = ( {R}_{f 1} {I}_{1} + {R}_{f 2} {I}_{2} + {R}_{f 3} {I}_{3} ) / 3 , \qquad ( 5 )$$

where R_{f1}, R_{f2}, and R_{f3} denote the feedback resistors connected to TIAs 241a, 243a, and 245a, respectively. The summation and averaging may be implemented by the active voltage summation and averaging circuit.

ADC 250a may generate the first digital output Dout_1 by converting the input voltage into a digital signal. Similarly, ADC 250b may generate the second digital output (Dout_2) based on the outputs of TIAs 241b, 243b, . . . , 245b. ADC 250m may convert the outputs of the TIAs 241m, 243m, . . . , 245m into the mth digital output (Dout_m). A combination of the digital outputs generated by ADCs 250a, . . . , 250m may represent a computing result of the VMM operation and may be mapped back to output results Y.

The mechanisms for programming the crossbar circuit involve dynamic calculation of the scaling factor K in the linear mapping, which is adaptive to the programming performance of each column of the subarray, rather than using a predetermined value. Matrix A is approximated as the sum of the conductance of the crossbar subarrays scaled by K (A=K₁G₁+K₂G₂+ . . . +KₙGₙ). This dynamic scaling facilitates faster convergence when programming errors are small and ensures that the largest residual of each column decreases monotonically (converges) when programming errors are large. Specifically, even if a memory element in the next subarray is stuck and significantly deviates from the target, it cannot be further than the difference between Gₒₙ (a high conductance level) and G_{off} (a low conductance level), ensuring its residual is not larger than the previous largest residual. As the scaling factors K (the weights for subsequent subarrays) decrease, the remaining error also decreases, converging toward zero. Because the actual programming result is read and considered when calculating the next residual, the accuracy is maintained. Additionally, with the help of shrinking scaling factors, the effective precision of the entire array can exceed the device programming precision. In principle, arbitrarily high precision can be achieved by using an increasing number of subarrays. The chosen granularity of the scaling factor strikes a balance between using one scaler for the entire subarray and individual scaling factors for each device in the subarray. A global scaling factor for the entire subarray would reduce its effectiveness and be burdened by even a single inaccurate device, whereas individual scaling factors for every device would require excessive computation and would be inefficient to implement in hardware.

The proposed mapping mechanism can be implemented in hardware by programming the feedback resistor R_{f} in trans-impedance amplifier circuits and adding a row at the subarray for the offset B. The overhead for dynamic scaling factor calculation is negligible, requiring computation only once per subarray without additional array reading operations. This calculation has the same complexity as determining the programming voltage amplitudes for one cycle in the write-verify programming, typically taking multiple cycles. By dynamically calculating the weight, i.e., the scaling factor implemented by R_{f}, the mechanisms described herein efficiently utilize the existing ADC precision to achieve faster and more error-tolerant matrix programming.

The programming methods described herein may enable high-precision full vector-matrix multiplications. When input voltages are applied to the rows, switches of all subarrays are turned on simultaneously, and the output currents of all subarrays are naturally weighted and summed to obtain the total VMM result, which is then sent to the ADCs for final digitization. The entire VMM process is analog, with digitization occurring only at the final step. Multiple subarrays can share one ADC, saving significant area and power consumed by this component, as well as reducing the need for post-processing digital circuits such as bit shifters and adders for partial products used in the traditional approach. Additionally, the time and energy overheads associated with the input preprocessing circuit of the bit-slicing approach are eliminated by the mechanisms described herein.

FIG. 2B is a schematic diagram 200B illustrating an example 220 of a memory element in accordance with some embodiments of the present disclosure. As shown, memory element 220 may connect a bit line (BL) 2211, a select line (SEL) 2213, and a word line (WL) 2215. The bit line 2211 and the word line 2215 may be a bit line and a word line as described in connection with FIG. 2A, respectively.

Memory element 220 may include a memristor 2201 and a transistor 2203. A transistor may include three terminals, which may be marked as gate (G), source(S), and drain (D), respectively. The transistor 2203 may be serially connected to memristor 2201. As shown in FIG. 2B, the first electrode of the memristor 2201 may be connected to the drain of transistor 2203. The second electrode of the memristor 2201 may be connected to the bit line 2211. The source of the transistor 2203 may be connected to the word line 2215. The gate of the transistor 2203 may be connected to the select line 2213. Memory element 220 may also be referred to as a one-transistor-one-resistor (1T1R) configuration. The transistor 2203 may perform as a selector as well as a current controller, which may set the current compliance to the Memristor 2201 during programming. The gate voltage on transistor 2203 can set current compliances to memory element 220 during programming and can thus control the conductance and analog behavior of memory element 220. For example, when memory element 220 is set from a high-resistance state to a low-resistance state, a set signal (e.g., a voltage signal, a current signal) may be provided via the bit line (BL) 2211. Another voltage, also referred to as a select voltage or gate voltage, may be applied via the select line (SEL) 2213 to the transistor gate to open the gate and set the current compliance, while the word line (WL) 2215 may be set to ground. When memory element 220 is reset from the low-resistance state to the high-resistance state, a gate voltage may be applied to the gate of the transistor 2203 via the select line 2213 to open the transistor gate. Meanwhile, a reset signal may be sent to the memristor 2201 via the word line 2215, while the bit line 2211 may be set to ground.

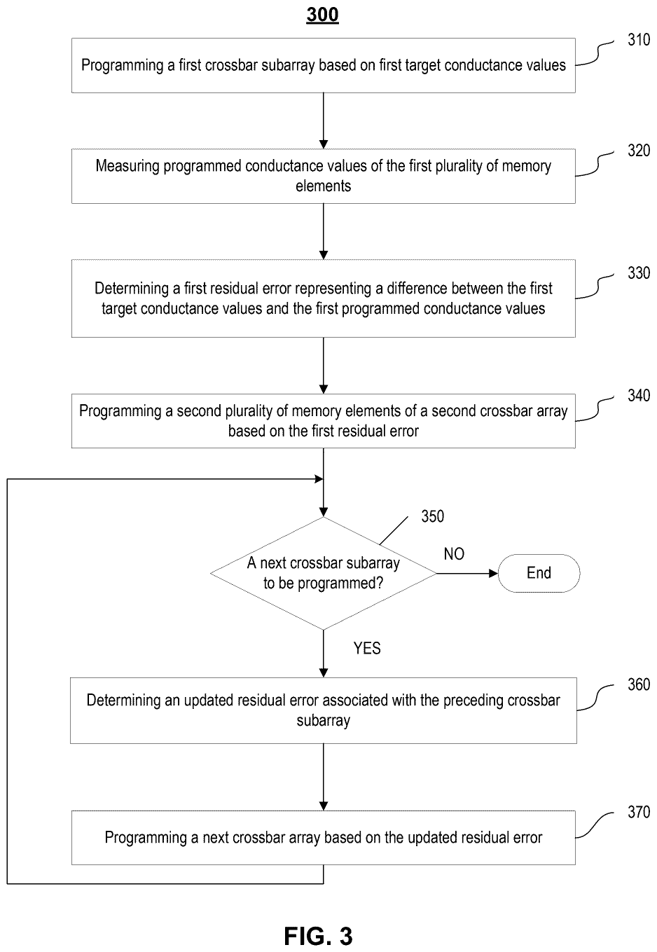

FIG. 3 is a flowchart illustrating an example process 300 for programming a crossbar circuit in accordance with some embodiments of the present disclosure. The crossbar circuit may be and/or include a crossbar circuit 200 as described in connection with FIG. 2A.

Process 300 may start at 310, where a first crossbar subarray may be programmed based on first target conductance values. For example, one or more programming signals (e.g., programming voltages or programming currents) may be applied to a first plurality of memory elements in the first crossbar array to program the first plurality of memory elements to the first target conductance values. The first target conductance values may be represented as a first conductance matrix G_{1_target} and may be determined by mapping an initial residual matrix A to a first target conductance matrix (G_{1_target}) within the programmable conductance range of the memory elements of a first crossbar subarray of the crossbar circuit.

At block 320, first programmed conductance values of the first plurality of memory elements may be measured. For example, a first read operation may be performed by applying a known voltage across each of the first plurality of memory elements and measuring the resulting current that flows through the memory element. The conductance value is then calculated based on the ratio of the measured current to the applied voltage. The programmed conductance values of the first plurality of memory after the application of the first programming signals may be represented as a first programmed conductance matrix G₁.

At 330, a first residual error associated with the programming of the first crossbar subarray may be determined. The first residual error may represent a difference between the first target conductance values and the first programmed conductance values. For example, the first programmed conductance matrix G₁ may be inversely mapped to a first numerical matrix A₁. A first residual matrix representative of a difference between the first numerical matrix A₁ and the initial residual matrix A may then be determined. More particularly, R₁=A−A₁ is determined, where R₁ denotes the first residual matrix.

At 340, a second crossbar subarray may be programmed based on the first residual error. For example, a second target conductance matrix may be determined by mapping the first residual matrix (R₁) to a second target conductance matrix (G_{2_target}) within the programmable conductance range of the memory elements in the second crossbar subarray. A second plurality of memory elements in the second crossbar array may then be programmed by applying a second plurality of programming signals to the second plurality of memory elements.

At 350, a determination may be made as to whether one or more crossbar subarrays are to be programmed. For example, if the previously programmed crossbar subarray is the last crossbar subarray to be programmed (“No” at 350), process 300 may conclude. Matrix A is approximated as the sum of scaled conductance values of the programmed crossbar subarray (A=K₁G₁+K₂G₂+ . . . +KₙGₙ).

Alternatively, if at least one crossbar subarray is to be programmed (“YES” at 350), process 300 may proceed to block 360 and may calculate an updated residual error associated with the preceding crossbar array. For example, a second residual error representing a difference between the second target conductance values and the conductance values of the second plurality of memory elements after programming (the “second programmed conductance values”) may be determined. In particular, the programmed conductance values of the second plurality of memory elements in the second crossbar subarray may be determined (e.g., by performing a second read operation). G₂ may be inversely mapped to a second numerical matrix A₂. The second residual matrix R₂ may be determined based on equation (3).

At block 370, a next crossbar subarray may be programmed based on the residual error associated with the proceeding current crossbar array. For example, an updated target conductance matrix may be determined based on the updated residual matrix by mapping the updated residual material to a target conductance matrix within the programmable conductance range of the memory elements of the next crossbar array. For example, a third conductance matrix may be determined by mapping the second residual matrix to a second target conductance matrix within the programmable conductance range of the memory elements of a third crossbar array of the crossbar circuit. The next crossbar array may then be programmed based on the updated target conductance matrix. For example, a third crossbar array may be programmed based on the third target conductance matrix.

Process 300 may be executed in an iterative manner until the crossbar subarrays to be used to perform a VMM are all programmed. The subarrays are dynamically compensated for programming errors (residual errors) of the previously programmed arrays.

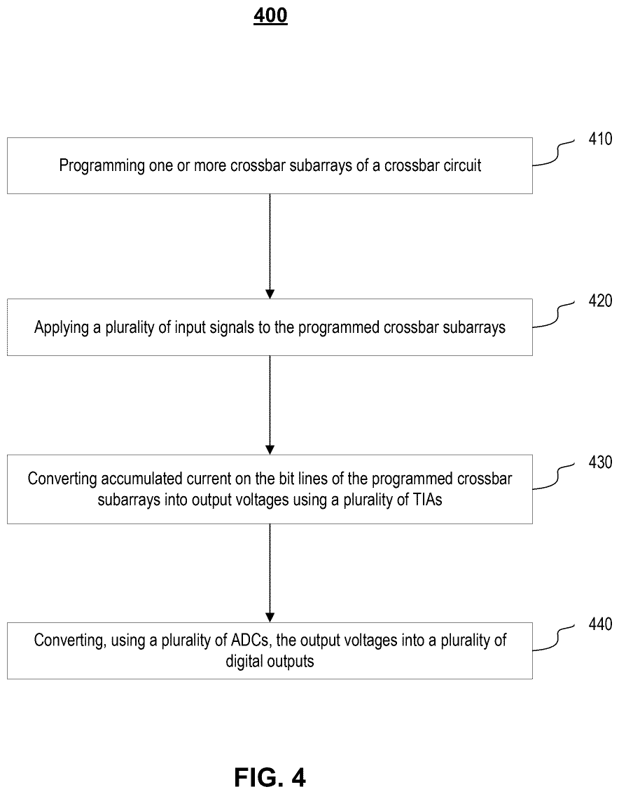

FIG. 4 is a flowchart illustrating an example process 400 for performing a VMM operation using a crossbar circuit in accordance with some embodiments of the present disclosure. The VMM operation may be represented as Y=XA. The crossbar circuit may be and/or include a crossbar circuit 200 as described in connection with FIG. 2A.

Process 400 may start at 410, where one or more crossbar subarrays of the crossbar circuit may be programmed based on a target conductance matrix. The target conductance matrix may correspond to matrix A and may be generated by mapping matrix A to conductance values of memory elements of one or more crossbar subarrays. A certain number of the crossbar subarrays of the crossbar circuit may be programmed to achieve predetermined programming precision. The crossbar subarrays may be programmed to dynamically compensate for residual errors associated with previously programmed crossbar subarrays as described in connection with FIGS. 2A and 3.

At 420, a plurality of input signals may be applied to the programmed crossbar subarrays. The input signals may be voltage signals, current signals, etc. that may represent an input matrix (X) on which the VMM is to be performed. The input signals may be applied to the word lines of the programmed crossbar subarrays.

At 430, a plurality of trans-impedance amplifiers (TIAs) may convert the accumulated current on the bit lines of the programmed crossbar subarrays into output voltages. For example, a first TIA (e.g., TIA 241a of FIG. 2A) may be connected to a first bit line (e.g., bit line 213a_1 of the first crossbar subarray 201a of FIG. 2A) and may generate a first output voltage representative of the accumulated current on the first bit line. A second TIA (e.g., TIA 243a of FIG. 2A) may be connected to a second bit line (e.g., bit line 213b_1 of the second crossbar subarray 201b of FIG. 2A) and may generate a second output voltage representative of the accumulated current on the second bit line. A third TIA (e.g., TIA 245a of FIG. 2A) may be connected to a third bit line (e.g., bit line 213j_1 of the third crossbar subarray 201j of FIG. 2A) and may generate a third voltage representative of the accumulated current on the third bit line. As another example, a fourth TIA (e.g., TIA 241b of FIG. 2A) may be connected to a fourth bit line (e.g., bit line 213a_2 of the first crossbar subarray 201a of FIG. 2A) and may generate a fourth output voltage representative of the accumulated current on the fourth bit line. A fifth TIA (e.g., TIA 243b of FIG. 2A) may be connected to a fifth bit line (e.g., bit line 213b_2 of the second crossbar subarray 201b of FIG. 2A) and may generate a fifth output voltage representative of the accumulated current on the fifth bit line. A sixth TIA (e.g., TIA 245b of FIG. 2A) may be connected to a sixth bit line (e.g., bit line 213j_2 of the third crossbar subarray 201j of FIG. 2A) and may generate a sixth output voltage representative of the accumulated current on the sixth bit line.

At 440, one or more ADCs may convert the output voltages into a plurality of digital outputs. Each ADC may convert the output voltages of the TIAs connected to the ADC into a digital output. For example, the outputs of the first TIA, the second TIA, and the third TIA may be provided to a first ADC (e.g., ADC 250a of FIG. 2A) as input. The first ADC may generate a first digital output based at least in part on the first voltage, the second voltage, and the third voltage. The first digital output may be generated by digitizing a weighted sum of the outputs of the TIAs connected to the first ADC. As another example, the outputs of the fourth TIA, the fifth TIA, and the sixth TIA may be provided to a second ADC (e.g., ADC 250b of FIG. 2A) as input. The second ADC may generate a second digital output based at least in part on the fourth voltage, the fifth voltage, and the sixth voltage. A combination of the digital outputs may represent the result of the VMM operation.

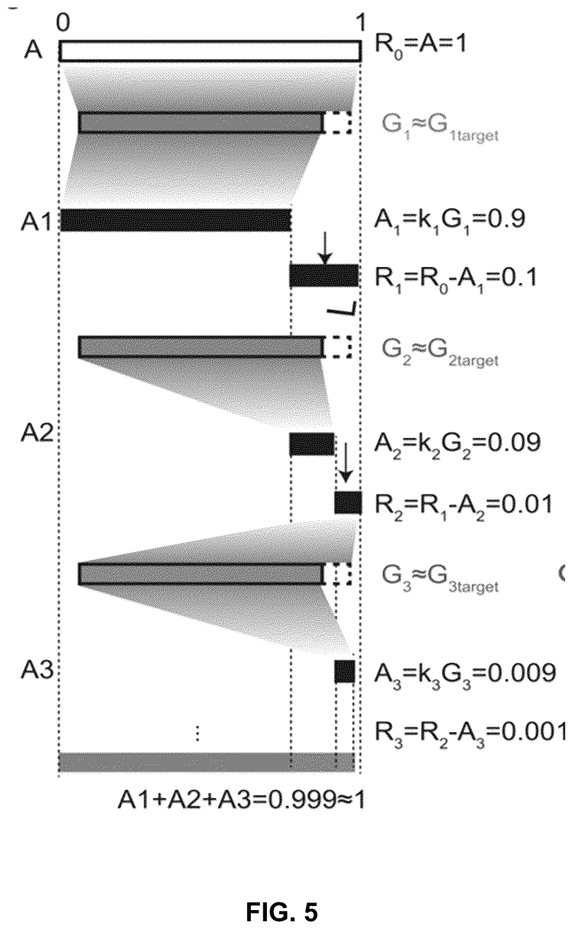

FIG. 5 is a diagram illustrating residual errors involved in programming a numerical value using three crossbar subarrays in accordance with some embodiments of the present disclosure.

As shown, a number a=1 may be into a first memory element of a first crossbar subarray, a second memory element of a second crossbar subarray, and a third memory element of a third crossbar subarray. In this example, the first memory element ended up with a 10% residual error, either by one-shot programming or by a read-verify feedback programming method with a few programming cycles, as it was programmed to be 0.9 instead of 1. After reading the programming result of this first memory element, a second memory element can be programmed to compensate for this error. The second memory element likely also had a 10% residual error and was programmed to 0.9, for example. A weight of less than 1 (e.g., 0.1) was used for the second device to ensure the error scales down, with which the second device rep resented 0.9×0.1=0.09. Therefore, the combined value of those two memory elements became 0.9+0.1×0.9=0.99, successfully reducing the total error to only 1% by only two sequential programming operations. Similarly, adding a third memory element further reduced the total error to 0.1%.

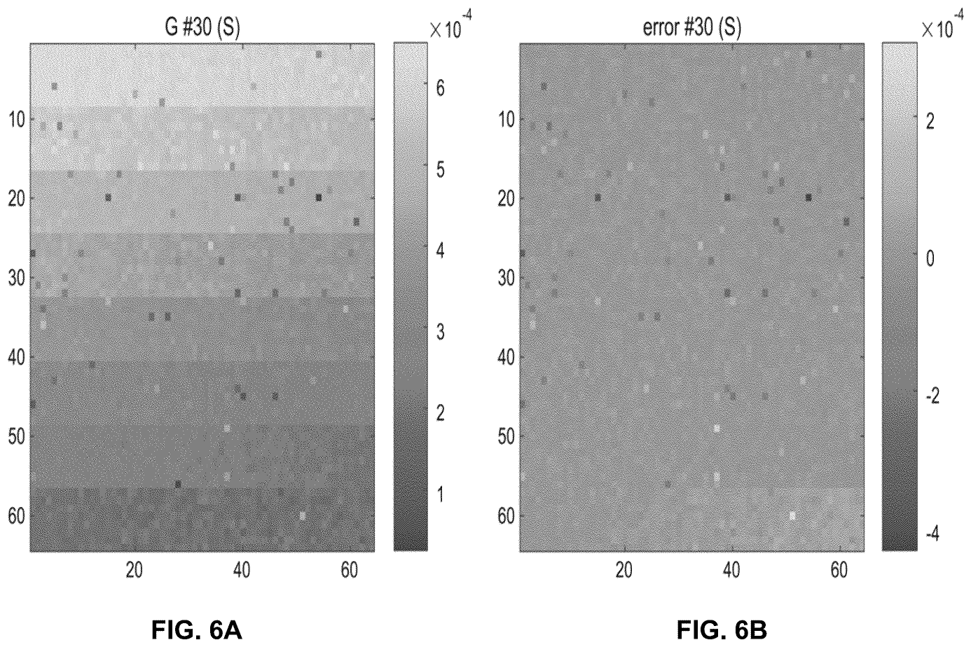

FIG. 6A illustrates a final conductance map of a 64×64 region after 30 programming cycles performed on a crossbar circuit in accordance with some embodiments of the present disclosure. FIG. 6B illustrates an absolute error map after 30 programming cycles performed on the crossbar circuit described in connection with FIG. 6A.

The crossbar circuit architecture and programming methods may be employed to solve partial differential equations (PDEs). This application has been analyzed using two memristor platforms. The first platform consists of a non-fully integrated system that includes laboratory-produced memristors with larger device variations. This system features a 128×64 one transistor-one resistor (1T1R) memristor crossbar array and associated printed circuit board (PCB) driving circuits. The second platform comprises a fully integrated System on Chip (SoC) that incorporates fabricated memristors with enhanced uniformities from a commercial foundry. This SoC is an analog in-memory computing accelerator with ten neural processing units (NPUs), each equipped with a 256×256 memristor array that exhibits superior yield and uniformity compared to laboratory-produced memristors.

The effectiveness of the mechanisms described herein has been demonstrated on both platforms, accommodating large and small device variances effectively. The SoC platform, in particular, has shown promising performance capabilities. Each memristive cell in these platforms is capable of being programmed in an analog manner, with conductance levels adjustable from 30 to 700 μS by modulating the gate voltage of the transistor in the 1T1R configuration. Specific regions of the array can be programmed to multilevel patterns within 30 programming cycles. However, some variability in device performance, if unaddressed, could significantly impact the accuracy of vector-matrix multiplication operations and hinder the convergence of the PDE solver.

Conjugate gradient methods are a class of iterative algorithms used to solve large linear systems of equations that are hard to solve with direct methods. They are particularly useful for symmetric positive-definite systems, and they can converge to the exact solution in a relatively small number of iterations. However, the convergence rate of these methods can be slowed down by the presence of eigenvalues clustered near zero or widely separated, which can make the condition number of the system large.

One way to improve the convergence of conjugate gradient methods is to use a preconditioner, a matrix that transforms the original linear system into a new one with a better condition number. PCG is the quickest and most reliable method for solving symmetric positive definite matrices. Green's function preconditioner is a type of preconditioner that uses Green's function of the differential operator in the original system to construct a matrix approximating the inverse of the original. It has been shown to be effective in accelerating the convergence of conjugate gradient methods for a wide range of problems, including those arising in fluid dynamics, electromagnetics, and quantum mechanics.

The programming methods described herein have been validated through their implementation in an on-chip crossbar utilized as a vector-matrix multiplication (VMM) core within a high-precision partial differential equation (PDE) solver. This solver employs a preconditioned conjugate gradient (PCG) algorithm, which, compared to the standard conjugate gradient (CG) method, leverages a preconditioning matrix to enhance the condition number of the system being solved, thereby accelerating convergence.

Incorporating a high-precision VMM core into the hardware enables optimizations that were previously unattainable. The software-hardware codesign can utilize a more efficient Green's function as the preconditioner for various problems. This approach is in contrast to the commonly employed Jacobi (diagonal) preconditioner favored in digital solvers for its computational simplicity. The use of a more complex but efficient preconditioner facilitates faster convergence compared to digital solvers that use simpler preconditioners.

Furthermore, the architecture is designed to handle multiple subarrays on the chip, enabling the division of a problem of a certain size into a coarser mesh of a reduced size for effective hardware preconditioning. This feature allows for enhanced scalability and adaptability in solving complex computational problems.

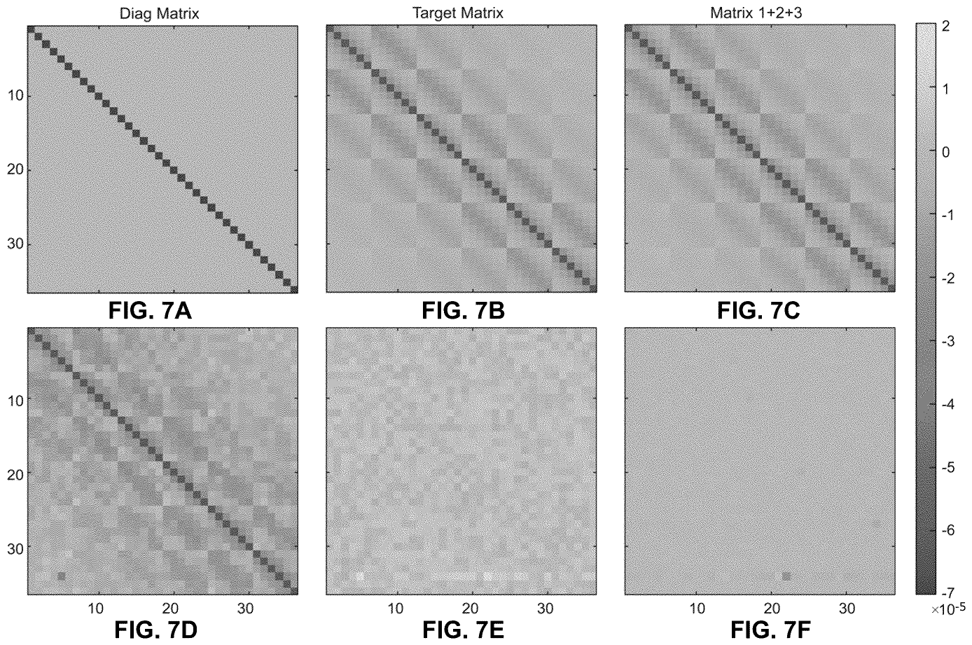

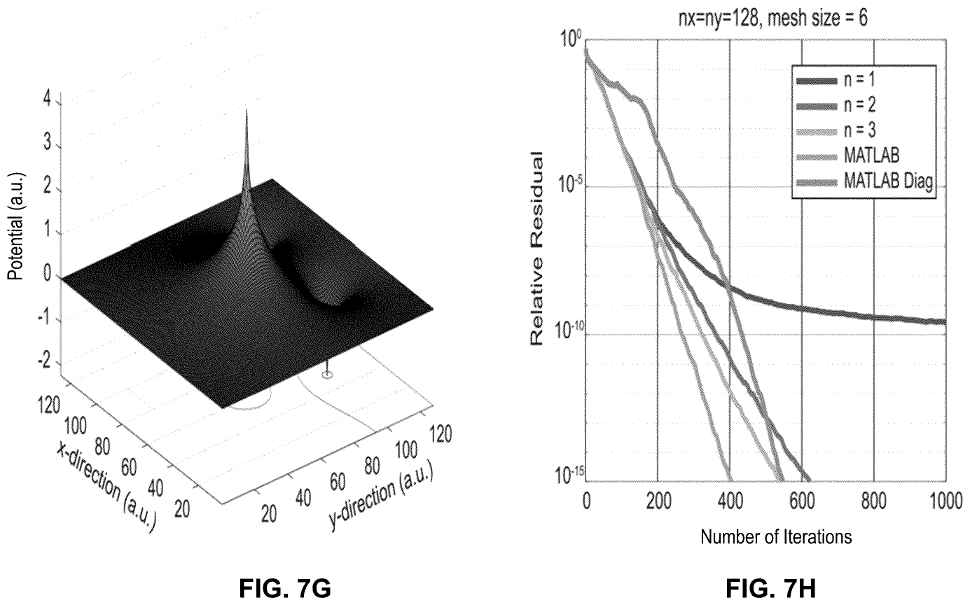

FIGS. 7A-7H show experimental results from a Poisson solver utilizing arbitrary precision programming across three crossbar subarrays. FIG. 7A depicts a traditional diagonal preconditioner for a Poisson problem. FIG. 7B shows the target Green's function preconditioner matrix. FIG. 7C demonstrates the summation of three numerical matrices: A1+A2+A3. FIG. 7D illustrates a conductance map of the first subarray, programmed and corresponding to the first numerical matrix A1. FIG. 7E illustrates a conductance map of the second subarray, programmed and corresponding to the second numerical matrix A2. FIG. 7F shows a conductance map of the third subarray, programmed and corresponding to the third numerical matrix A3. FIG. 7G displays the correct solution of a 128×128 Poisson equation example by the hardware solver using all three subarrays on a SoC. FIG. 7H depicts the solution's residual over iterative processes with different settings; results for n=1, 2, 3 were obtained experimentally using the SoC, whereas MATLAB and MATLAB diagonal results were derived from software solvers.

Poisson's equation (expressed as Δf=h where h is the source) is widely solved in electrostatics to find the electrical potential for a given charge distribution h. As an example, a crossbar circuit described herein may solve a Poisson equation with nₓ=n_{y}=128 grids by downsampling it into a jₓ=j_{y}=6 mesh in a hardware preconditioning process. In this hardware preconditioning step, the input matrix may be flattened as a 1×36 vector to multiply with the flattened 2D physical preconditioner matrix. Hence, the size of the preconditioner matrix needed was 36×36 per subarray. A traditional diagonal preconditioner for the Poisson problem is shown in FIG. 7A. The Green's function for the Poisson equation was calculated explicitly and reshaped to 2D for hardware VMM and is illustrated in FIG. 7B. Up to three subarrays were experimentally programmed to the target Green's function preconditioner matrix for hardware VMM in the PCG algorithm, so the total number of physical devices used is 108×36. The programmed subarrays A₁ to A₃ are shown in FIGS. 7D-7F, and the effective matrix (FIG. 7C) was the summation of A₁ to A₃. Compared with the traditional single matrix approach (FIG. 7D), FIG. 7C was much closer to the target in FIG. 7B.

The same initial condition of one source and two sinks with different numbers of subarrays enabled may be solved in the VMM operation to see the differences in the solution obtained. With only the first subarray of lab-made memristors (non-fully integrated platform), the preconditioner could not be effectively reconstructed in hardware.

Thus, the solution did not converge correctly, which revealed the subpar performance of a normal memristor crossbar in scientific computing without using the mechanisms described herein. When using two or more subarrays, the obtained solution converged to the correct value (FIG. 7G). Compared with similar previous work that achieved 2.7% mean absolute error in hardware VMM, the precision of the solution improved enormously as more subarrays were used for VMM, and up to 10-15 precision was obtained with three subarrays within 600 iterations (FIG. 7H). Using more subarrays would bring the residual curve closer to the theoretical curve of using Green's function preconditioner, ultimately converging to the theoretical curve. Using a diagonal preconditioner was slower than using Green's function preconditioner because it contained less information and was less effective.

Because of the experimental reading variation, there were slight variations on the residual curve for each run, which did not change the above general observations. Techniques such as time multiplexing are not required, as all subarrays could compute simultaneously, greatly improving the throughput.

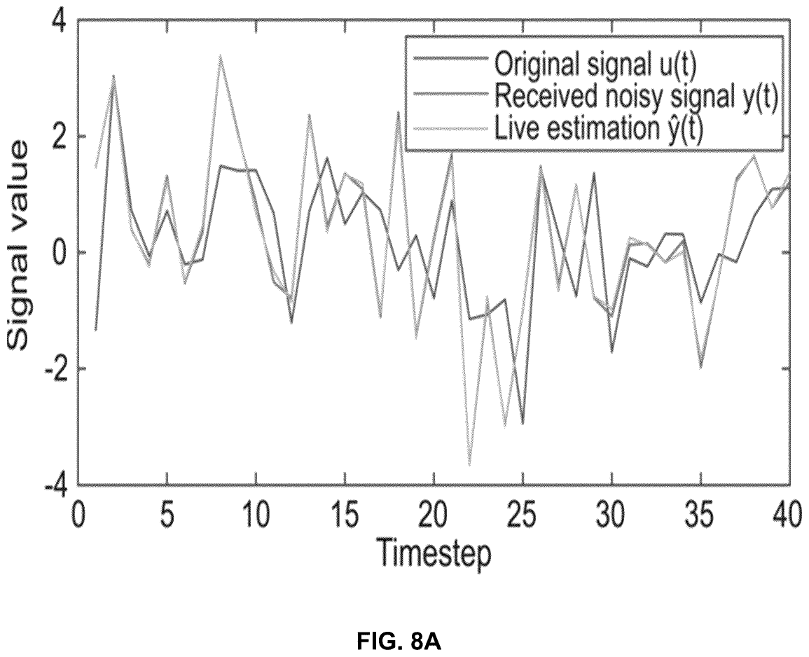

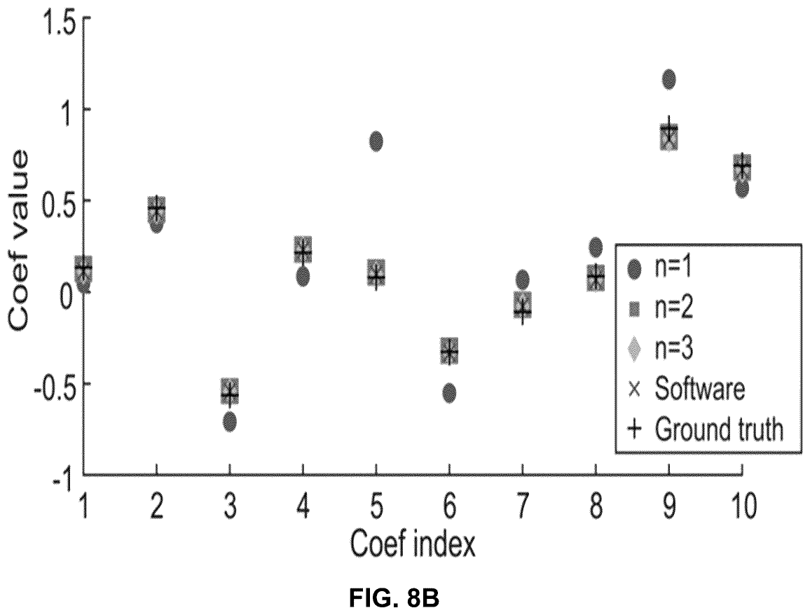

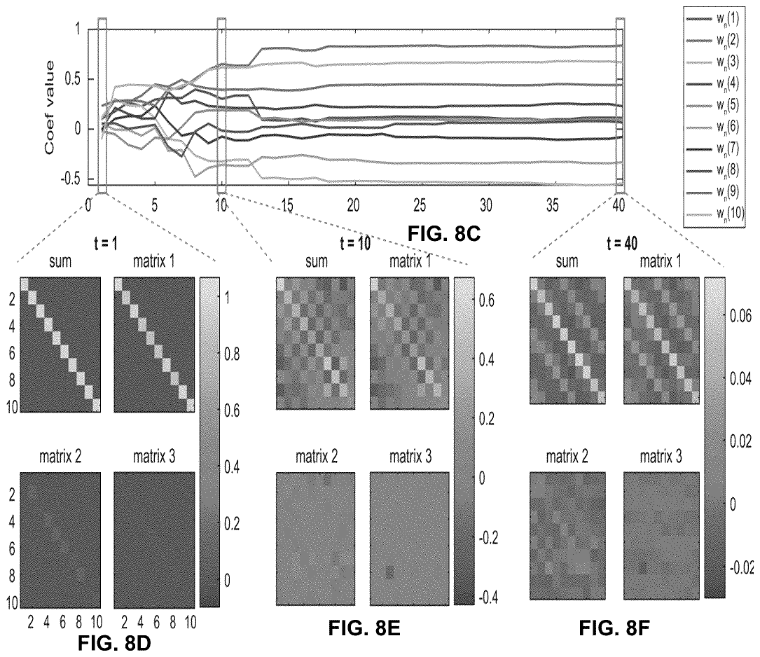

FIGS. 8A-8F illustrate experimental results relating to a hardware implementation of a recursive least-squares filter with arbitrary precision programming. FIG. 8A illustrates an original randomly generated signal u(t), the received noisy signal y(t) after passing through an echoey channel, and the live estimation of the noise-free signal y\hat{ }(t). FIG. 8B illustrates the estimated coefficients of the channel along with the ground truth. Experiments using n=1˜3 subarrays are performed. Using two or more subarrays yields results nearly identical to those of the software estimation. FIG. 8C depicts the history of the coefficient estimations over 40 timesteps, with each line representing one coefficient of the channel. FIG. 8D depicts the covariance matrix and the numerical matrices of the three subarrays at t=1. FIG. 8E illustrates the covariance matrix and the numerical matrices of the three subarrays at t=10. FIG. 8F illustrates the covariance matrix and the numerical matrices of the three subarrays at t=40.

The PCG algorithm uses a fixed matrix, and a changing matrix is used in the hardware recursive least squares (RLS) filter application.

Recursive least squares (RLS) is an adaptive filter algorithm that recursively finds the coefficients that minimize a weighted linear least squares cost function relating to the input signals. Suppose a signal x(n) is transmitted over an echoey, noisy channel, it will be received as

$$y ( n ) = {\sum }_{k = 0}^{q} {w}_{n} ( k ) x ( n - k ) + v ( n ) ,$$

where v(n) represents additive noise. The RLS filter can be used to estimate the channel coefficients w with wₙ and recover the noise-free version of the received signal, ŷ(n)=wₙxₙ, so that ŷ(n) is close to y(n) in the least squares sense. For the p-th order RLS filter, the algorithm runs as follows: where α is the prior estimation error, λ is the forgetting factor, g is the Kalman gain, and P is the covariance matrix.

$$For n = 1 , 2 , …$$

$${x}_{n} = {[ x ( n ) , x ( n - 1 ) , … , x ( n - p ) ]}^{T}$$

$$a ( n ) = y ( n ) - {x}^{T} ( n ) w ( n - 1 )$$

$$g ( n ) = P ( n - 1 ) x ( n ) {\{ λ + {x}^{T} ( n ) P ( n - 1 ) x ( n ) \}}^{- 1}$$

$$P ( n ) = {λ}^{- 1} P ( n - 1 ) - g ( n ) {x}^{T} ( n ) P ( n - 1 )$$

$$w ( n ) = w ( n - 1 ) + a ( n ) g ( n ) .$$

An example problem may be set up as follows: the window size is t=10, which is also the filter order, so there are 10 coefficients to be estimated. The input signal x(n) are normally distributed random numbers from the standard normal distribution N(0,1), and the coefficients are normally distributed random numbers [0.1344, 0.4585, −0.5647, 0.2155, 0.0797, −0.3269, −0.1084, 0.0857, 0.8946, 0.6924]. λ=0.97.

Suppose a signal x(n) is transmitted over an echoey, noisy channel. It will be received as

$$y ( n ) = {\sum }_{k = 0}^{q} {w}_{n} ( k ) x ( n - k ) + v ( n ) ,$$

where v(n) represents additive noise. The RLS filter can be used to estimate the channel coefficients wₙ and recover the noise-free version of the received signal, y\hat{ }(n) (FIG. 8A). At each timestep, it uses the last step's estimation to update the next step. The crossbar array served as the covariance matrix, which was critical in updating the Kalman gain and estimating the coefficients. In this example problem, the noisy window was assumed to be t=10; thus, 10 coefficients were estimated, and the covariance matrix was 10×10. The experiments were done with one subarray, two subarrays, and three subarrays. Their corresponding estimated coefficients are shown in FIG. 8B, along with the software estimation and the ground truth that was randomly generated when setting up the problem. One subarray was not sufficient to accurately estimate the channel coefficients, but two or three subarrays substantially improved the result that overlapped with the software estimation. The updating history of coefficients is shown in FIG. 8C, with covariance matrices on three typical timesteps shown in FIG. 8D to FIG. 8F. The covariance matrix was updated in hardware in each timestep. It was observed that it changed from the initial diagonal matrix to a checkerboard-like shape in the middle and finally changed to a banded matrix when the estimation became stable. This verified the capability and stability of our programming scheme for dynamic matrices that change during computation.

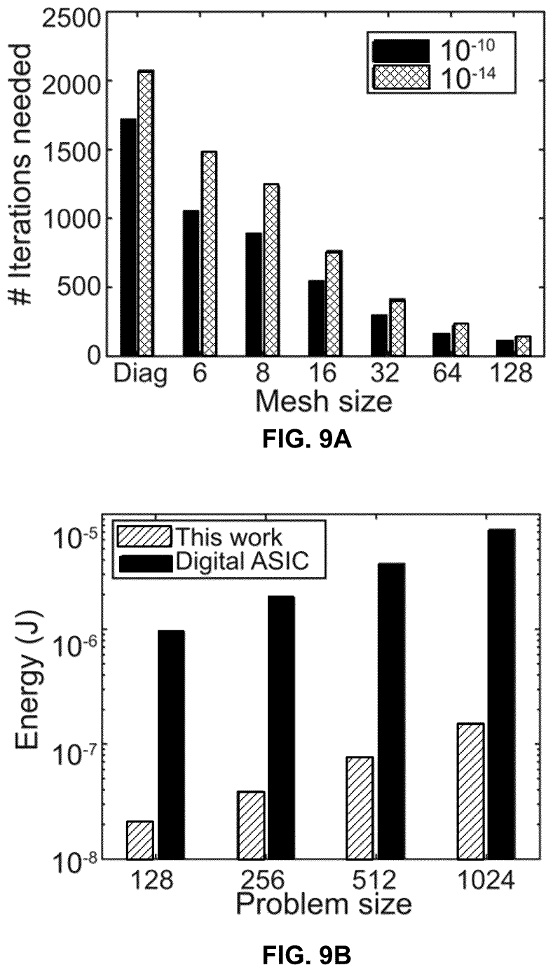

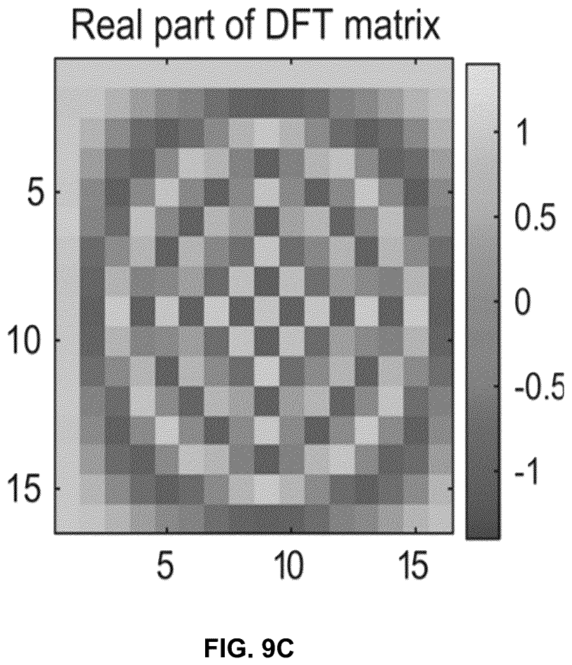

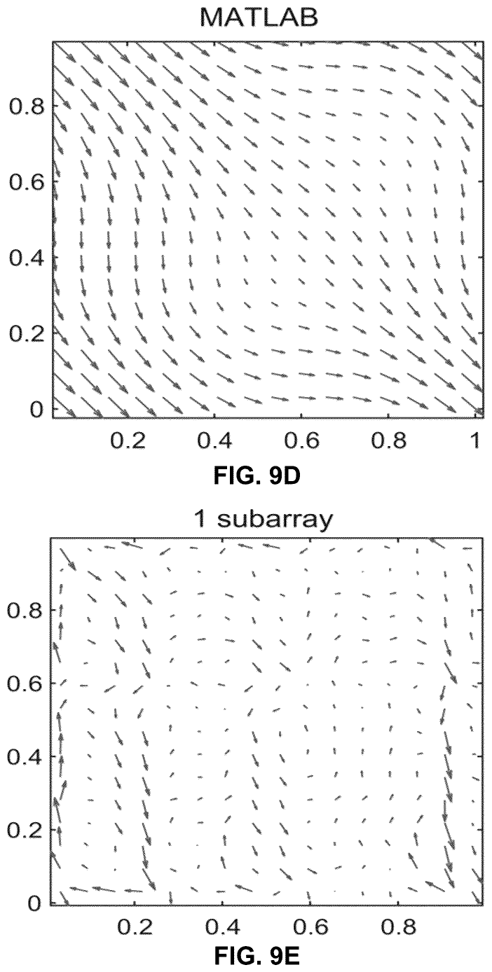

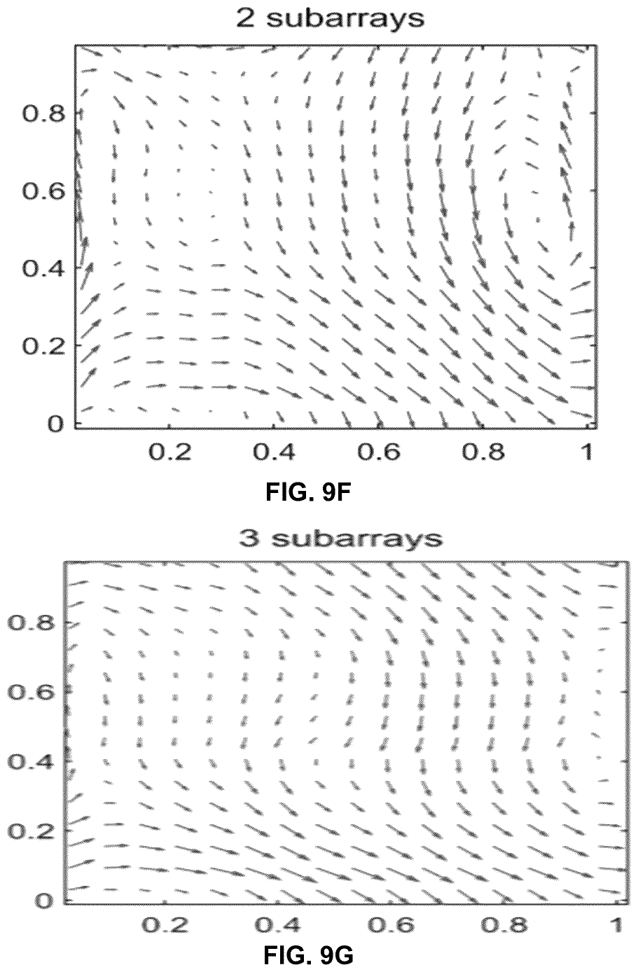

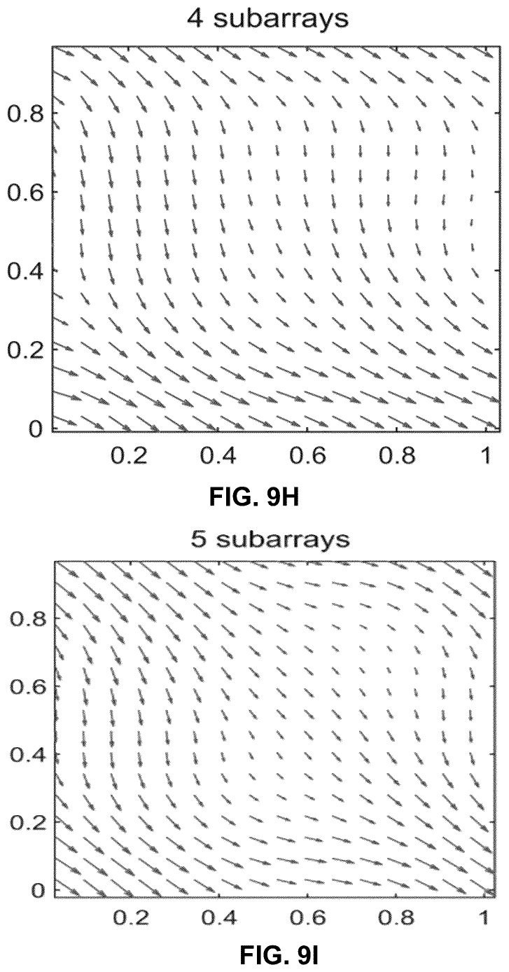

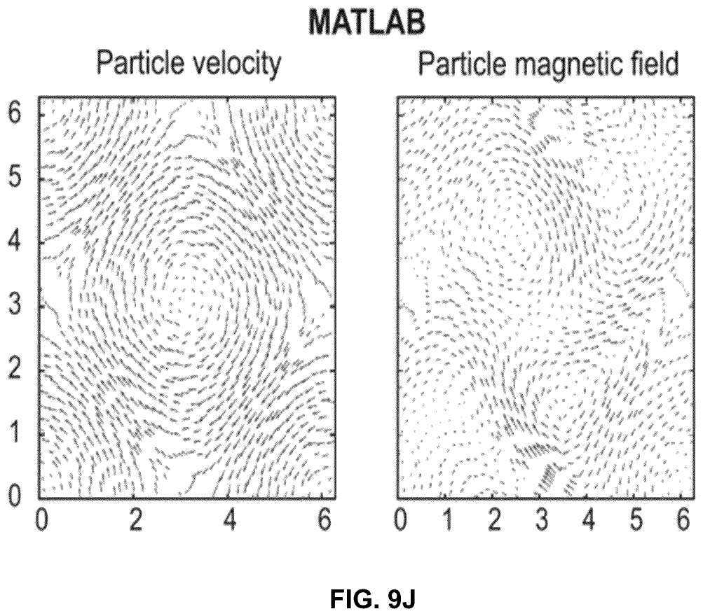

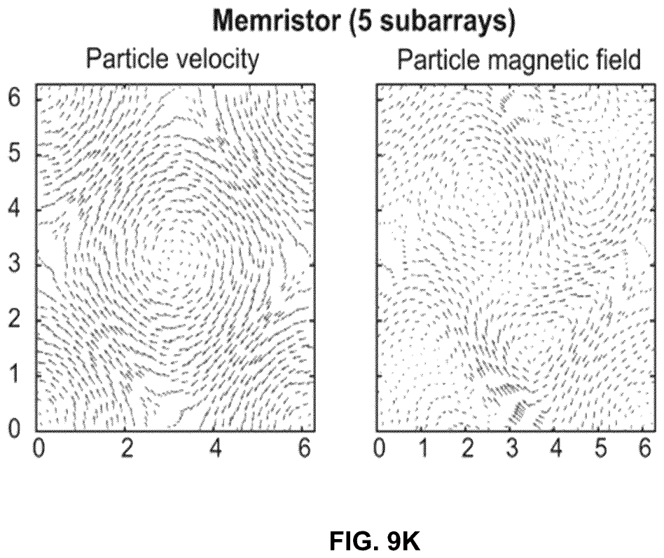

FIG. 9A is a graph illustrating the number of iterations needed for convergence across various mesh sizes for two tolerance levels, 10⁻¹⁰ and 10⁻¹⁴, showing that the number of iterations for convergence reduces when the mesh size increases. FIG. 9B is a graph illustrating the energy consumption of a crossbar circuit in accordance with the present disclosure compared with an ASIC design running at approximately the same speed. FIG. 9C illustrates the real part of the DFT matrix (n=16) used in a Navier-Stokes (N-S) equation solver. FIG. 9D is a quiver plot illustrating the solved velocity field of an N-S equation at t=4.8 s solved by MATLAB. FIGS. 9E-9I are quiver plots illustrating the solved velocity field of an N-S equation at t=4.8 s solved by memristor simulation using one to five subarrays. FIG. 9J is a quiver plot illustrating the solved velocity and magnetic flux density field of an MHD problem at 1=2 by MATLAB. FIG. 9K is a quiver plot illustrating the solved velocity and magnetic flux density field of an MHD problem at t=2 by memristor simulation using five subarrays. Each arrow in the quiver plots FIG. 9D to FIG. 9K shows the direction and relative magnitude of the described field.

The Navier-Stokes equations are a set of coupled nonlinear partial differential equations that are difficult to solve analytically, especially for complex geometries or turbulent flows. Here we are solving a simple case with the incompressible flow:

$$\frac{\partial u}{\partial t} + ( u \cdot ∇ ) u - v {∇}^{2} u = - ∇ ( \frac{p}{{ρ}_{0}} ) + g ,$$

where u is the velocity, v is the kinetic viscosity, p is the pressure and g is the body accelerations. An example problem may be setup as follows: problem size is nₓ=n_{y}=16 points in a bounded Lₓ=L_{y}=1 space with v=0.001 and g=0. The initial velocity field u=

$$( {u}_{x} , {u}_{y} ) = ( {\sum }_{i = 1}^{3} {A}_{i} {f}_{y , i} sin ( {f}_{x , i} \frac{2 π}{{n}_{x}} x + {s}_{x , i} ) cos ( {f}_{y , i} \frac{2 π}{{n}_{y}} y + {s}_{y , i} ) , - {\sum }_{i = 1}^{3} {A}_{i} {f}_{x , i} cos ( {f}_{x , i} \frac{2 π}{{n}_{x}} x + {s}_{x , i} ) sin ( {f}_{y , i} \frac{2 π}{{n}_{y}} y + {s}_{y , i} ) )$$

is the composition of 3 sinusoidal waves, where the coefficients are A=[1.0,0.6,0.3], fₓ=[3.0,5.0,7.0], sₓ=[1.2,0.0,0.5], f_{y}=[4.0,3.0,7.0], s_{y}=[5.0,0.0,0.5]. Simulation timestep dt=0.05, number of timestep=150. The unit is arbitrary.

MHD can be described by a set of equations consisting of a continuity equation, an equation of motion, an equation of state, Ampère's Law, Faraday's law, and Ohm's law. Here we are solving a simple case where the pressure p is isotropic and adiabatic index γ, electrical resistivity η and kinetic viscosity v are all constant scalers. A fluid with velocity u and magnetic field B can be described by the continuity equation

$$\frac{\partial ρ}{\partial t} = - u \cdot ∇ ρ - ρ ∇ \cdot u ,$$

the equation of state

$$\frac{\partial p}{\partial t} = - u \cdot ∇ p - γ p ∇ \cdot u ,$$

the equation of motion

$$ρ \frac{\partial u}{\partial t} = - ρ u \cdot ∇ u - ∇ p - \frac{1}{{μ}_{0}} ∇ \frac{{B}^{2}}{2} + \frac{1}{{μ}_{0}} B ∇ \cdot B + v {∇}^{2} u ,$$

and the induction equation

$$\frac{\partial B}{\partial t} = ∇ \times ( u \times B ) - ∇ \times [ η ( ∇ \times B ) ] ,$$

which comes from Ohm's law, Ampere's law, and Faraday's law.

An example problem can be set up as follows. The problem space is periodic with Lₓ=L_{y}=2π and is divided into nₓ=n_{y}=16 grids. All quantities are normalized before calculation. Normalized ρ₀=1, v=0.1, η=0.1, and γ=1. The initial particle velocity field is u=(uₓ, u_{y})=(−sin((y+0.5)*2π*n_{y}), sin((x+0.5)*2π*nₓ)). The initial Magnetic flux density is B=(Bₓ, B_{y})=(−0.2 sin ((y+0.5)*2π*n_{y}, 0.2 sin(2(y+0.5)*2π*nₓ)). Timestep dt=0.02 and the number of timesteps=100. The mesh size for the Green's function preconditioner is jₓ=j_{y}=6.

As to the scalability, increasing the mesh size reduced the iterations needed to achieve a specific solution precision, and the numbers of iterations required to obtain 10⁻¹⁰ and 10⁻¹⁴ precision on a 512×512 problem were listed in FIG. 9A. The comparison of the energy performance with a highly optimized digital system with an application-specific integrated circuit (ASIC), which exhibited an energy efficiency of 7.02 tera-operations per second per watt and a latency of 10.4 ns, almost the same speed as a crossbar circuit described herein, indicates that the crossbar circuit described herein obtained nearly two orders of magnitude energy advantage over the digital system (FIG. 9B).

The programming methods described herein proved more valuable when solving complicated time-evolving problems such as N-S equations and MHD problems. When solving those equations, a subsequent timestep needed to be calculated based on the result of the previous timesteps, so even tiny errors in the previous step could accumulate and propagate, making a high precision critical for each timestep. Our approach was a general programming approach that can serve not only as the preconditioners but also any other matrices, for instance, the discrete Fourier transform (DFT) matrices (FIG. 9C). As an example, N-S equations are solved in a simulation of the motion of fluids over time using a spectral method and n=1˜5 subarrays. The simulated velocity field (FIGS. 9E-9I) became closer to the MATLAB solver (FIG. 9D) as more subarrays were used. In each timestep, the solution was transformed to the spectral space by multiplying with the DFT matrix and transformed back to the physical space using the inverse DFT after the pressure and diffusion effects were applied in the frequency domain. The input matrix and the DFT matrix were divided into real and imaginary parts to process complex number multiplication.

One advantage of such spectral methods is that they can achieve high accuracy with relatively few grid points. The Fourier transform and inverse Fourier transform were highly parallelizable but could be computationally expensive, which is a perfect example to be solved by the hardware VMM using memristive crossbars. As a last example, we solved complicated MHD problems in which the fluid flow and magnetic fields were coupled together, by exploiting both our hardware FFT technique in solving the N-S subproblem and hardware PCG technique in solving the pressure and magnetic field pressure. The simulated fields with five subarrays nearly perfectly matched our MATLAB solver within 100 timesteps (FIGS. 9J and 9K).

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A method, comprising:
programming a first plurality of memory elements of a first crossbar subarray based on first target conductance values;
determining first programmed conductance values of the first plurality of memory elements by performing a read operation;
determining a first residual error representing a difference between the first target conductance values and the first programmed conductance values; and
programming a second plurality of memory elements of a second crossbar subarray based on the first residual error.

2. The method of claim 1, wherein programming the first plurality of memory elements of the first crossbar subarray comprises applying a first plurality of programming signals to the first plurality of memory elements.

3. The method of claim 1, the first target conductance values are determined by mapping an initial residual matrix to a first target conductance matrix within a programmable conductance range of the first plurality of memory elements.

4. The method of claim 1, wherein programming the second plurality of memory elements of the second crossbar subarray based on the first residual error comprises:
determining second target conductance values based on the first residual error; and
programming the second plurality of memory elements of the second crossbar subarray based on the second target conductance values.

5. The method of claim 4, further comprising:
determining a second residual error representing a difference between the second target conductance values and second programmed conductance values of the second plurality of memory elements; and
programming a third plurality of memory elements of a third crossbar subarray based on the second residual error.

6. The method of claim 5, wherein programming the second plurality of memory elements of the second crossbar subarray based on the first residual error comprises mapping the first residual error to a second target conductance matrix.

7. The method of claim 5, wherein programming the second plurality of memory elements of the second crossbar subarray based on the second target conductance values comprises applying a second plurality of programming signals to the second plurality of memory elements.

8. The method of claim 1, wherein the first plurality of memory elements is connected to a first plurality of bit lines and a first plurality of word lines, and wherein the second plurality of memory elements is connected to a second plurality of bit lines and a second plurality of word lines.

9. The method of claim 8, further comprising:
generating, using an analog-to-digital converter, a digital output based at least in part on a first output voltage and a second output voltage, wherein the first output voltage represents first accumulated current on a first bit line of the first plurality of bit lines, and wherein the second output voltage represents second accumulated current on a second bit line of the second plurality of bit lines.

10. The method of claim 9, further comprising:
generating, using a first trans-impedance amplifier connected to the first bit line of the first plurality of bit lines, the first output voltage; and
generating, using a second trans-impedance amplifier connected to the second bit line of the second plurality of bit lines, the second output voltage.

11. The method of claim 1, wherein the first plurality of memory elements comprises at least one of a memristor, a phase-change memory (PCM) device, a floating gate device, a spintronic device, or a ferroelectric device.

12. A crossbar circuit, comprising:
a first crossbar subarray comprising a first plurality of word lines, a first plurality of bit lines, and a first plurality of memory elements connected to the first plurality of word lines and the first plurality of bit lines;
a second crossbar subarray comprising a second plurality of word lines, a second plurality of bit lines, and a second plurality of memory elements connected to the second plurality of word lines and the second plurality of bit lines;
a first trans-impedance amplifier (TIA) connected to a first bit line of the first plurality of bit lines;
a second TIA connected to a second bit line of the second plurality of bit lines; and
a first analog-to-digital converter (ADC) configured to generate a first digital output based at least in part on a first output voltage of the first TIA and a second output voltage of the second TIA.

13. The crossbar circuit of claim 12, wherein the first TIA is configured to generate the first output voltage based on accumulated current on the first bit line, and wherein the second TIA is configured to generate the second output voltage based on accumulated current on the second bit line.

14. The crossbar circuit of claim 12, further comprising:
a third crossbar subarray comprising a third plurality of word lines, a third plurality of bit lines, and a third plurality of memory elements connected to the third plurality of word lines and the third plurality of bit lines; and
a third TIA connecting to a third bit line of the third plurality of bit lines, wherein the first ADC is further configured to generate the first digital output based at least in part on a third output voltage of the third TIA.

15. The crossbar circuit of claim 14, further comprising:
a fourth TIA connected to a fourth bit line of the first plurality of bit lines;
a fifth TIA connected to a fifth bit line of the second plurality of bit lines; and
a second ADC configured to generate a second digital output based at least in part on a fourth output voltage of the fourth TIA and a fifth output voltage of the fifth TIA.

16. The crossbar circuit of claim 15, further comprising:
a sixth TIA connected to a sixth bit line of the third plurality of bit lines, wherein the second ADC is further configured to generate the second digital output based at least in part on a sixth output voltage of the sixth TIA.

17. The crossbar circuit of claim 12, further comprising a programming circuit configured to:
program the first plurality of memory elements based on first target conductance values;
perform a first read operation to determine programmed conductance values of the first plurality of memory elements;
determine a first residual error representing a difference between the first target conductance values and the first programmed conductance values; and
program the second plurality of memory elements based on the first residual error.

18. The crossbar circuit of claim 17, wherein the programming circuit is further configured to:
determine second programmed conductance values of the second plurality of memory elements;
determine a second residual error representing a difference between the second target conductance values and the second programmed conductance values; and
program a third plurality of memory elements of a third crossbar subarray based on the second residual error.

19. The crossbar circuit of claim 12, wherein the first plurality of memory elements comprises at least one of a memristor, a phase-change memory (PCM) device, a floating gate device, a spintronic device, or a ferroelectric device.

20. The crossbar circuit of claim 12, wherein the first plurality of memory elements comprises a one-transistor-one-resistor (1T1R) configuration.
